(19) United States
(12) Patent Application Publication
(10) Pub. No.: US 2015/0124401 A1
(43) Pub. Date: May 7, 2015

(54) CONSUMER ELECTRONICS PORT HAVING BULK AMORPHOUS ALLOY CORE AND A DUCTILE CLADDING

(71) Applicants: Christopher D. Prest, San Francisco, CA (US); Matthew S. Scott, San Jose, CA (US); Stephen P. Zadesky, Portola Valley, CA (US); Richard W. Heley, Palo Alto, CA (US); Dermot J. Stratton, San Francisco, CA (US); Joseph C. Poole, San Francisco, CA (US)

(72) Inventors: Christopher D. Prest, San Francisco, CA (US); Matthew S. Scott, San Jose, CA (US); Stephen P. Zadesky, Portola Valley, CA (US); Richard W. Heley, Palo Alto, CA (US); Dermot J. Stratton, San Francisco, CA (US); Joseph C. Poole, San Francisco, CA (US)

(21) Appl. No.: 14/397,587

(22) PCT Filed: May 4, 2012
(86) PCT No.: PCT/US12/36638

§ 371 Date: Oct. 28, 2014

(51) Int. Cl. H05K 5/04; C23C 4/06; H05K 5/02; B32B 37/06; B32B 37/10; G06F 1/16; C23C 4/12; B23K 20/00

(52) U.S. Cl. CPC H05K 5/04; C23C 4/124; C23C 4/127; C23C 4/125; C23C 4/122; C23C 4/06; B23K 20/002; B32B 37/06; B32B 37/10; G06F 1/1656; H05K 5/0247
USPC 361/679.55; 156/308.2; 228/196; 427/287; 427/448

(57) ABSTRACT

Disclosed herein are consumer electronics housings made from bulk-solidifying amorphous alloy materials having a ductile coating applied to all or a portion of the bulk-solidifying amorphous alloy. Also disclosed are methods of making consumer electronic housings from bulk-solidifying amorphous alloy materials such that at least a portion of the bulk-solidifying amorphous alloy housing is coated with a ductile cladding material.

### FIELD OF THE INVENTION

Disclosed herein are consumer electronics housings made from bulk-solidifying amorphous alloy materials having a ductile coating applied to all or a portion of the bulk-solidifying amorphous alloy. Also disclosed are methods of making consumer electronic housings from bulk-solidifying amorphous alloy materials such that at least a portion of the bulk-solidifying amorphous alloy housing is coated with a ductile cladding material.

### BACKGROUND

A conventional electronic device can be functionally separated for convenience into two portions: an electronics portion, which provides the functional utility of the electronic device; and an external frame portion which provides physical protection to the electronics portion. To provide optimum protection, the frame physically encapsulates the working components (such as including one or more microprocessors, memory devices, storage devices) of the electronic device: such as a portable computer, personal data assistant (“PDA”), or cell-phone.

For example, in portable personal computers, commonly referred to as notebook computers, a housing formed from a top case and a bottom case is used to support and house a screen, a computer, and interface devices. Typically, the case also forms a mounting structure for fastening together the various components comprising the computer. The various components, including the logic board and disk drives, are attached to either the upper or lower half of the case by means of screws or other such fastening means. Electromagnetic Interference (“EMI”) protection is incorporated into the case by placing a sheet of shielding material inside both halves of the case or by surrounding the relevant components with a metal structure which isolates them from the environment. In constructing a typical notebook computer case, or any portable electronic device case, an effort is made to minimize overall weight while maximizing the device's processing power, memory storage and shock resistance.

From a material standpoint, although plastic and composites are light weight and easily processable into the complex shapes required for most electronics cases, the structural strength and durability available from a plastic or composite material is typically not as good as that obtainable from metal. In addition, a separate EMI protection layer must be interposed between the case and electronics when using a plastic or composite material instead of a metal. The weight and cost penalty for fabricating the entire case from metal or metal alloys, however, is usually too great for a portable electronic device, except in such specialty markets as the military. For example, attempts have been made to correct the strength and durability problems associated with plastic cases by forming a portable computer where the case is made from die-cast metal upper and lower halves. Although this creates a relatively strong and durable computer, it weighs too much for easy portability and the cost of such a computer is too high. Other manufactures have made various subassemblies from sheet metal but the resulting computer is not noticeably stronger. In addition, most conventional metals are very difficult to adequately shape.

Magnesium alloys have been proposed for use in forming housings of consumer electronics devices, although casting thin layers of magnesium has proven difficult. Use of bulk-solidifying amorphous alloys to form a metal frame or housing for consumer electronics devices also has been proposed in, for example, U.S. Patent Application Publication No. 2003/0062811, the disclosure of which is incorporated by reference herein in its entirety. These alloy materials, while having improved strength and durability, can be brittle. Accordingly, use of such alloy materials at or near an input port or jacks on the device may cause some or a portion to crack or break.

It is known to coat certain metal or metal alloy surfaces with corrosion and wear resistant materials that are less brittle than the underlying metal. Such coating techniques are disclosed in, for example, U.S. Pat. No. 5,019,163, and U.S. Patent Application Publication Nos. 2005/0196633, 2007/0065679, 2010/0330393, and 2011/0027608, the disclosures of each of which is incorporated by reference herein in their entireties. The coatings can be applied using various coating techniques, including electroless, coating, molten metal or alloy bath coating, chemical vapor deposition, plasma deposition, sputter deposition.

It would be desirable to provide a housing or frame for a consumer electronics device made from a bulk-solidifying amorphous alloy, in which at least the portions of the electronics device that surround ports or input jacks have improved ductility and are less susceptible to cracking and failure.

### SUMMARY

A proposed solution according to embodiments herein is to provide a consumer electronics device housing or frame made from a bulk-solidifying amorphous alloy core in which at least a portion of the housing or frame is clad in a ductile material. In accordance with one embodiment, there is provided a consumer electronics device having a housing including at least a bulk-solidifying amorphous alloy, at least one input/output port or jack, and a ductile coating at least over the bulk-solidifying amorphous alloy adjacent the at least one input/output port or jack.

In accordance with another embodiment, there is provided a method of making a housing for a consumer electronics device that includes forming the housing from at least a bulk-solidifying amorphous alloy, the housing including at least one input/output port or jack. The method also includes positioning a ductile material adjacent the at least one input/output port or jack, and then joining the ductile material to the bulk-solidifying amorphous alloy.

In accordance with another embodiment, there is provided a method of making a housing for a consumer electronics device that includes forming the housing from at least a bulk-solidifying amorphous alloy, the housing including at least one input/output port or jack. The method also includes coating a ductile material on the bulk-solidifying amorphous alloy in at least the area of the bulk-solidifying amorphous alloy that is adjacent to the at least one input/output port or jack.

### BRIEF DESCRIPTION OF THE DRAWINGS

FIG. 1 provides a temperature-viscosity diagram of an exemplary bulk solidifying amorphous alloy.

FIG. 2 provides a schematic of a time-temperature-transformation (TTT) diagram for an exemplary bulk solidifying amorphous alloy.

FIG. 3 is perspective view of an illustrative portable electronic device having a housing made with a bulk-solidifying amorphous alloy having a ductile metal or metal alloy positioned in an area adjacent at least one input/output port or jack in accordance with an embodiment.

FIG. 4 is a side view of the bottom of the portable electronic device of FIG. 3, showing the areas of the input/output ports or jacks surrounded by a ductile material.

FIG. 5 is a side view of a portion of the housing of the portable electronic device of FIG. 3 illustrating a method of providing a ductile material in areas adjacent input/output ports or jacks in accordance with an embodiment.

FIG. 6 is a side view of a portion of the housing of the portable electronic device of FIG. 3 illustrating a method of providing a ductile material in areas adjacent input/output ports or jacks in accordance with another embodiment.

FIG. 7 illustrates a quaternary phase diagram illustrating a compositional range for forming a joint between a bulk-solidifying amorphous alloy material and a ductile material.

### DETAILED DESCRIPTION

All publications, patents, and patent applications cited in this Specification are hereby incorporated by reference in their entirety.

The articles “a” and “an” are used herein to refer to one or to more than one (i.e., to at least one) of the grammatical object of the article. By way of example, “a polymer resin” means one polymer resin or more than one polymer resin. Any ranges cited herein are inclusive. The terms “substantially” and “about” used throughout this Specification are used to describe and account for small fluctuations. For example, they can refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

Bulk-solidifying amorphous alloys, or bulk metallic glasses (“BMG”), are a recently developed class of metallic materials. These alloys may be solidified and cooled at relatively slow rates, and they retain the amorphous, non-crystalline (i.e., glassy) state at room temperature. Amorphous alloys have many superior properties than their crystalline counterparts. However, if the cooling rate is not sufficiently high, crystals may form inside the alloy during cooling, so that the benefits of the amorphous state can be lost. For example, one challenge with the fabrication of bulk amorphous alloy parts is partial crystallization of the parts due to either slow cooling or impurities in the raw alloy material. As a high degree of amorphicity (and, conversely, a low degree of crystallinity) is desirable in BMG parts, there is a need to develop methods for casting BMG parts having controlled amount of amorphicity.

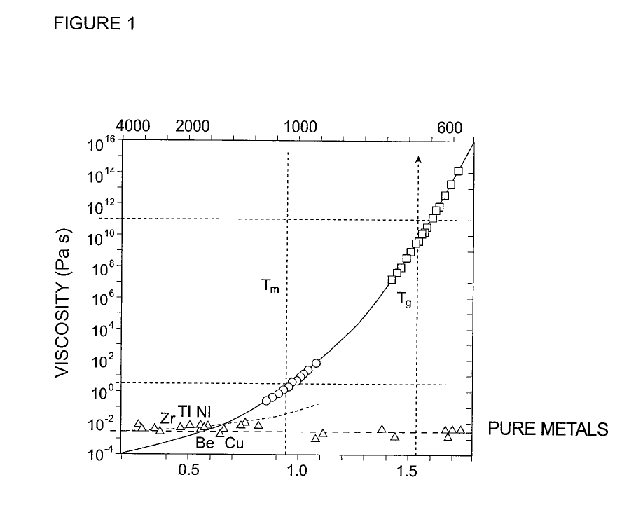

FIG. 1 (obtained from U.S. Pat. No. 7,575,040) shows a viscosity-temperature graph of an exemplary bulk solidifying amorphous alloy, from the VIT-001 series of Zr—Ti—Ni—Cu—Be family manufactured by Liquidmetal Technology. It should be noted that there is no clear liquid/solid transformation for a bulk solidifying amorphous metal during the formation of an amorphous solid. The molten alloy becomes more and more viscous with increasing undercooling until it approaches solid form around the glass transition temperature. Accordingly, the temperature of solidification front for bulk solidifying amorphous alloys can be around glass transition temperature, where the alloy will practically act as a solid for the purposes of pulling out the quenched amorphous sheet product.

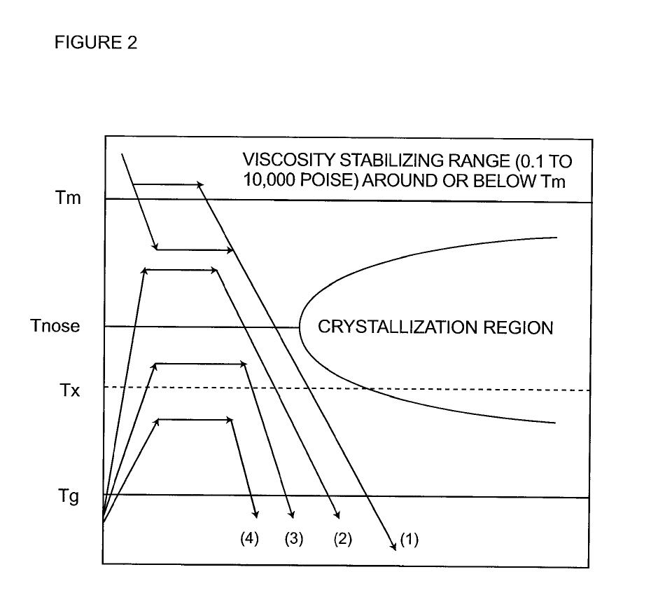

FIG. 2 (obtained from U.S. Pat. No. 7,575,040) shows the time-temperature-transformation (TTT) cooling curve of an exemplary bulk solidifying amorphous alloy, or TTT diagram. Bulk-solidifying amorphous metals do not experience a liquid/solid crystallization transformation upon cooling, as with conventional metals. Instead, the highly fluid, non crystalline form of the metal found at high temperatures (near a “melting temperature” Tm) becomes more viscous as the temperature is reduced (near to the glass transition temperature Tg), eventually taking on the outward physical properties of a conventional solid.

Even though there is no liquid/crystallization transformation for a bulk solidifying amorphous metal, a “melting temperature” Tm may be defined as the thermodynamic liquidus temperature of the corresponding crystalline phase. Under this regime, the viscosity of bulk-solidifying amorphous alloys at the melting temperature could lie in the range of about 0.1 poise to about 10,000 poise, and even sometimes under 0.01 poise. A lower viscosity at the “melting temperature” would provide faster and complete filling of intricate portions of the shell/mold with a bulk solidifying amorphous metal for forming the BMG parts. Furthermore, the cooling rate of the molten metal to form a BMG part has to such that the time-temperature profile during cooling does not traverse through the nose-shaped region bounding the crystallized region in the TTT diagram of FIG. 2. In FIG. 2, Tnose is the critical crystallization temperature Tx where crystallization is most rapid and occurs in the shortest time scale.

The supercooled liquid region, the temperature region between Tg and Tx is a manifestation of the extraordinary stability against crystallization of bulk solidification alloys. In this temperature region the bulk solidifying alloy can exist as a high viscous liquid. The viscosity of the bulk solidifying alloy in the supercooled liquid region can vary between 1012 Pa s at the glass transition temperature down to 105 Pa s at the crystallization temperature, the high temperature limit of the supercooled liquid region. Liquids with such viscosities can undergo substantial plastic strain under an applied pressure. The embodiments herein make use of the large plastic formability in the supercooled liquid region as a forming and separating method.

One needs to clarify something about Tx. Technically, the nose-shaped curve shown in the TTT diagram describes Tx as a function of temperature and time. Thus, regardless of the trajectory that one takes while heating or cooling a metal alloy, when one hits the TTT curve, one has reached Tx. In FIG. 2, Tx is shown as a dashed line as Tx can vary from close to Tm to close to Tg.

The schematic TTT diagram of FIG. 2 shows processing methods of die casting from at or above Tm to below Tg without the time-temperature trajectory (shown as (1) as an example trajectory) hitting the TTT curve. During die casting, the forming takes place substantially simultaneously with fast cooling to avoid the trajectory hitting the TTT curve. The processing methods for superplastic forming (SPF) from at or below Tg to below Tm without the time-temperature trajectory (shown as (2), (3) and (4) as example trajectories) hitting the TTT curve. In SPF, the amorphous BMG is reheated into the supercooled liquid region where the available processing window could be much larger than die casting, resulting in better controllability of the process. The SPF process does not require fast cooling to avoid crystallization during cooling. Also, as shown by example trajectories (2), (3) and (4), the SPF can be carried out with the highest temperature during SPF being above Tnose or below Tnose, up to about Tm. If one heats up a piece of amorphous alloy but manages to avoid hitting the TTT curve, you have heated “between Tg and Tm”, but one would have not reached Tx.

Typical differential scanning calorimeter (DSC) heating curves of bulk-solidifying amorphous alloys taken at a heating rate of 20 C/min describe, for the most part, a particular trajectory across the TTT data where one would likely see a Tg at a certain temperature, a Tx when the DSC heating ramp crosses the TTT crystallization onset, and eventually melting peaks when the same trajectory crosses the temperature range for melting. If one heats a bulk-solidifying amorphous alloy at a rapid heating rate as shown by the ramp up portion of trajectories (2), (3) and (4) in FIG. 2, then one could avoid the TTT curve entirely, and the DSC data would show a glass transition but no Tx upon heating. Another way to think about it is trajectories (2), (3) and (4) can fall anywhere in temperature between the nose of the TTT curve (and even above it) and the Tg line, as long as it does not hit the crystallization curve. That just means that the horizontal plateau in trajectories might get much shorter as one increases the processing temperature.

### Phase

The term “phase” herein can refer to one that can be found in a thermodynamic phase diagram. A phase is a region of space (e.g., a thermodynamic system) throughout which all physical properties of a material are essentially uniform. Examples of physical properties include density, index of refraction, chemical composition and lattice periodicity. A simple description of a phase is a region of material that is chemically uniform, physically distinct, and/or mechanically separable. For example, in a system consisting of ice and water in a glass jar, the ice cubes are one phase, the water is a second phase, and the humid air over the water is a third phase. The glass of the jar is another separate phase. A phase can refer to a solid solution, which can be a binary, tertiary, quaternary, or more; solution, or a compound, such as an intermetallic compound. As another example, an amorphous phase is distinct from a crystalline phase.

### Metal, Transition Metal, and Non-Metal

The term “metal” refers to an electropositive chemical element. The term “element” in this Specification refers generally to an element that can be found in a Periodic Table. Physically, a metal atom in the ground state contains a partially filled band with an empty state close to an occupied state. The term “transition metal” is any of the metallic elements within Groups 3 to 12 in the Periodic Table that have an incomplete inner electron shell and that serve as transitional links between the most and the least electropositive in a series of elements. Transition metals are characterized by multiple valences, colored compounds, and the ability to form stable complex ions. The term “nonmetal” refers to a chemical element that does not have the capacity to lose electrons and form a positive ion.

Depending on the application, any suitable nonmetal elements, or their combinations, can be used. The alloy (or “alloy composition”) can comprise multiple nonmetal elements, such as at least two, at least three, at least four, or more, nonmetal elements. A nonmetal element can be any element that is found in Groups 13-17 in the Periodic Table. For example, a nonmetal element can be any one of F, Cl, Br, I, At, O, S, Se, Te, Po, N, P, As, Sb, Bi, C, Si, Ge, Sn, Pb, and B. Occasionally, a nonmetal element can also refer to certain metalloids (e.g., B, Si, Ge, As, Sb, Te, and Po) in Groups 13-17. In one embodiment, the nonmetal elements can include B, Si, C, P, or combinations thereof Accordingly, for example, the alloy can comprise a boride, a carbide, or both.

A transition metal element can be any of scandium, titanium, vanadium, chromium, manganese, iron, cobalt, nickel, copper, zinc, yttrium, zirconium, niobium, molybdenum, technetium, ruthenium, rhodium, palladium, silver, cadmium, hafnium, tantalum, tungsten, rhenium, osmium, iridium, platinum, gold, mercury, rutherfordium, dubnium, seaborgium, bohrium, hassium, meitnerium, ununnilium, unununium, and ununbium. In one embodiment, a BMG containing a transition metal element can have at least one of Sc, Y, La, Ac, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, and Hg. Depending on the application, any suitable transitional metal elements, or their combinations, can be used. The alloy composition can comprise multiple transitional metal elements, such as at least two, at least three, at least four, or more, transitional metal elements.

The presently described alloy or alloy “sample” or “specimen” alloy can have any shape or size. For example, the alloy can have a shape of a particulate, which can have a shape such as spherical, ellipsoid, wire-like, rod-like, sheet-like, flake-like, or an irregular shape. The particulate can have any size. For example, it can have an average diameter of between about 1 micron and about 100 microns, such as between about 5 microns and about 80 microns, such as between about 10 microns and about 60 microns, such as between about 15 microns and about 50 microns, such as between about 15 microns and about 45 microns, such as between about 20 microns and about 40 microns, such as between about 25 microns and about 35 microns. For example, in one embodiment, the average diameter of the particulate is between about 25 microns and about 44 microns. In some embodiments, smaller particulates, such as those in the nanometer range, or larger particulates, such as those bigger than 100 microns, can be used.

The alloy sample or specimen can also be of a much larger dimension. For example, it can be a bulk structural component, such as an ingot, housing/casing of an electronic device or even a portion of a structural component that has dimensions in the millimeter, centimeter, or meter range.

### Solid Solution

The term “solid solution” refers to a solid form of a solution. The term “solution” refers to a mixture of two or more substances, which may be solids, liquids, gases, or a combination of these. The mixture can be homogeneous or heterogeneous. The term “mixture” is a composition of two or more substances that are combined with each other and are generally capable of being separated. Generally, the two or more substances are not chemically combined with each other.

### Alloy

In some embodiments, the alloy composition described herein can be fully alloyed. In one embodiment, an “alloy” refers to a homogeneous mixture or solid solution of two or more metals, the atoms of one replacing or occupying interstitial positions between the atoms of the other; for example, brass is an alloy of zinc and copper. An alloy, in contrast to a composite, can refer to a partial or complete solid solution of one or more elements in a metal matrix, such as one or more compounds in a metallic matrix. The term alloy herein can refer to both a complete solid solution alloy that can give single solid phase microstructure and a partial solution that can give two or more phases. An alloy composition described herein can refer to one comprising an alloy or one comprising an alloy-containing composite.

Thus, a fully alloyed alloy can have a homogenous distribution of the constituents, be it a solid solution phase, a compound phase, or both. The term “fully alloyed” used herein can account for minor variations within the error tolerance. For example, it can refer to at least 90% alloyed, such as at least 95% alloyed, such as at least 99% alloyed, such as at least 99.5% alloyed, such as at least 99.9% alloyed. The percentage herein can refer to either volume percent or weight percentage, depending on the context. These percentages can be balanced by impurities, which can be in terms of composition or phases that are not a part of the alloy.

### Amorphous or Non-Crystalline Solid

An “amorphous” or “non-crystalline solid” is a solid that lacks lattice periodicity, which is characteristic of a crystal. As used herein, an “amorphous solid” includes “glass” which is an amorphous solid that softens and transforms into a liquid-like state upon heating through the glass transition. Generally, amorphous materials lack the long-range order characteristic of a crystal, though they can possess some short-range order at the atomic length scale due to the nature of chemical bonding. The distinction between amorphous solids and crystalline solids can be made based on lattice periodicity as determined by structural characterization techniques such as x-ray diffraction and transmission electron microscopy.

The terms “order” and “disorder” designate the presence or absence of some symmetry or correlation in a many-particle system. The terms “long-range order” and “short-range order” distinguish order in materials based on length scales.

The strictest form of order in a solid is lattice periodicity: a certain pattern (the arrangement of atoms in a unit cell) is repeated again and again to form a translationally invariant tiling of space. This is the defining property of a crystal. Possible symmetries have been classified in 14 Bravais lattices and 230 space groups.

Lattice periodicity implies long-range order. If only one unit cell is known, then by virtue of the translational symmetry it is possible to accurately predict all atomic positions at arbitrary distances. The converse is generally true, except, for example, in quasi-crystals that have perfectly deterministic filings but do not possess lattice periodicity.

Long-range order characterizes physical systems in which remote portions of the same sample exhibit correlated behavior. This can be expressed as a correlation function, namely the spin-spin correlation function:

In the above function, s is the spin quantum number and x is the distance function within the particular system. This function is equal to unity when x=x′ and decreases as the distance |x−x′| increases. Typically, it decays exponentially to zero at large distances, and the system is considered to be disordered. If, however, the correlation function decays to a constant value at large |x−x′|, then the system can be said to possess long-range order. If it decays to zero as a power of the distance, then it can be called quasi-long-range order. Note that what constitutes a large value of |x−x′| is relative.

A system can be said to present quenched disorder when some parameters defining its behavior are random variables that do not evolve with time (i.e., they are quenched or frozen)—e.g., spin glasses. It is opposite to annealed disorder, where the random variables are allowed to evolve themselves. Embodiments herein include systems comprising quenched disorder.

The alloy described herein can be crystalline, partially crystalline, amorphous, or substantially amorphous. For example, the alloy sample/specimen can include at least some crystallinity, with grains/crystals having sizes in the nanometer and/or micrometer ranges. Alternatively, the alloy can be substantially amorphous, such as fully amorphous. In one embodiment, the alloy composition is at least substantially not amorphous, such as being substantially crystalline, such as being entirely crystalline.

In one embodiment, the presence of a crystal or a plurality of crystals in an otherwise amorphous alloy can be construed as a “crystalline phase” therein. The degree of crystallinity (or “crystallinity” for short in some embodiments) of an alloy can refer to the amount of the crystalline phase present in the alloy. The degree can refer to, for example, a fraction of crystals present in the alloy. The fraction can refer to volume fraction or weight fraction, depending on the context. A measure of how “amorphous” an amorphous alloy is can be amorphicity. Amorphicity can be measured in terms of a degree of crystallinity. For example, in one embodiment, an alloy having a low degree of crystallinity can be said to have a high degree of amorphicity. In one embodiment, for example, an alloy having 60 vol % crystalline phase can have a 40 vol % amorphous phase.

### Amorphous Alloy or Amorphous Metal

An “amorphous alloy” is an alloy having an amorphous content of more than 50% by volume, preferably more than 90% by volume of amorphous content, more preferably more than 95% by volume of amorphous content, and most preferably more than 99% to almost 100% by volume of amorphous content. Note that, as described above, an alloy high in amorphicity is equivalently low in degree of crystallinity. An “amorphous metal” is an amorphous metal material with a disordered atomic-scale structure. In contrast to most metals, which are crystalline and therefore have a highly ordered arrangement of atoms, amorphous alloys are non-crystalline. Materials in which such a disordered structure is produced directly from the liquid state during cooling are sometimes referred to as “glasses.” Accordingly, amorphous metals are commonly referred to as “metallic glasses” or “glassy metals.” In one embodiment, a bulk metallic glass (“BMG”) can refer to an alloy, of which the microstructure is at least partially amorphous. However, there are several ways besides extremely rapid cooling to produce amorphous metals, including physical vapor deposition, solid-state reaction, ion irradiation, melt spinning, and mechanical alloying. Amorphous alloys can be a single class of materials, regardless of how they are prepared.

Amorphous metals can be produced through a variety of quick-cooling methods. For instance, amorphous metals can be produced by sputtering molten metal onto a spinning metal disk. The rapid cooling, on the order of millions of degrees a second, can be too fast for crystals to form, and the material is thus “locked in” a glassy state. Also, amorphous metals/alloys can be produced with critical cooling rates low enough to allow formation of amorphous structures in thick layers—e.g., bulk metallic glasses.

The terms “bulk metallic glass” (“BMG”), bulk amorphous alloy (“BAA”), and bulk solidifying amorphous alloy are used interchangeably herein. They refer to amorphous alloys having the smallest dimension at least in the millimeter range. For example, the dimension can be at least about 0.5 mm, such as at least about 1 mm, such as at least about 2 mm, such as at least about 4 mm, such as at least about 5 mm, such as at least about 6 mm, such as at least about 8 mm, such as at least about 10 mm, such as at least about 12 mm. Depending on the geometry, the dimension can refer to the diameter, radius, thickness, width, length, etc. A BMG can also be a metallic glass having at least one dimension in the centimeter range, such as at least about 1.0 cm, such as at least about 2.0 cm, such as at least about 5.0 cm, such as at least about 10.0 cm. In some embodiments, a BMG can have at least one dimension at least in the meter range. A BMG can take any of the shapes or forms described above, as related to a metallic glass. Accordingly, a BMG described herein in some embodiments can be different from a thin film made by a conventional deposition technique in one important aspect—the former can be of a much larger dimension than the latter.

Amorphous metals can be an alloy rather than a pure metal. The alloys may contain atoms of significantly different sizes, leading to low free volume (and therefore having viscosity up to orders of magnitude higher than other metals and alloys) in a molten state. The viscosity prevents the atoms from moving enough to form an ordered lattice. The material structure may result in low shrinkage during cooling and resistance to plastic deformation. The absence of grain boundaries, the weak spots of crystalline materials in some cases, may, for example, lead to better resistance to wear and corrosion. In one embodiment, amorphous metals, while technically glasses, may also be much tougher and less brittle than oxide glasses and ceramics.

Thermal conductivity of amorphous materials may be lower than that of their crystalline counterparts. To achieve formation of an amorphous structure even during slower cooling, the alloy may be made of three or more components, leading to complex crystal units with higher potential energy and lower probability of formation. The formation of amorphous alloy can depend on several factors: the composition of the components of the alloy; the atomic radius of the components (preferably with a significant difference of over 12% to achieve high packing density and low free volume); and the negative heat of mixing the combination of components, inhibiting crystal nucleation and prolonging the time the molten metal stays in a supercooled state. However, as the formation of an amorphous alloy is based on many different variables, it can be difficult to make a prior determination of whether an alloy composition would form an amorphous alloy.

Amorphous alloys, for example, of boron, silicon, phosphorus, and other glass formers with magnetic metals (iron, cobalt, nickel) may be magnetic, with low coercivity and high electrical resistance. The high resistance leads to low losses by eddy currents when subjected to alternating magnetic fields, a property useful, for example, as transformer magnetic cores.

Amorphous alloys may have a variety of potentially useful properties. In particular, they tend to be stronger than crystalline alloys of similar chemical composition, and they can sustain larger reversible (“elastic”) deformations than crystalline alloys. Amorphous metals derive their strength directly from their non-crystalline structure, which can have none of the defects (such as dislocations) that limit the strength of crystalline alloys. For example, one modern amorphous metal, known as Vitreloy™, has a tensile strength that is almost twice that of high-grade titanium. In some embodiments, metallic glasses at room temperature are not ductile and tend to fail suddenly when loaded in tension, which limits the material applicability in reliability-critical applications, as the impending failure is not evident. Therefore, to overcome this challenge, metal matrix composite materials having a metallic glass matrix containing dendritic particles or fibers of a ductile crystalline metal can be used. Alternatively, a BMG low in element(s) that tend to cause embitterment (e.g., Ni) can be used. For example, a Ni-free BMG can be used to improve the ductility of the BMG.

Another useful property of bulk amorphous alloys is that they can be true glasses; in other words, they can soften and flow upon heating. This can allow for easy processing, such as by injection molding, in much the same way as polymers. As a result, amorphous alloys can be used for making sports equipment, medical devices, electronic components and equipment, and thin films. Thin films of amorphous metals can be deposited as protective coatings via a high velocity oxygen fuel technique.

A material can have an amorphous phase, a crystalline phase, or both. The amorphous and crystalline phases can have the same chemical composition and differ only in the microstructure—i.e., one amorphous and the other crystalline. Microstructure in one embodiment refers to the structure of a material as revealed by a microscope at 25× magnification or higher. Alternatively, the two phases can have different chemical compositions and microstructures. For example, a composition can be partially amorphous, substantially amorphous, or completely amorphous.

As described above, the degree of amorphicity (and conversely the degree of crystallinity) can be measured by fraction of crystals present in the alloy. The degree can refer to volume fraction of weight fraction of the crystalline phase present in the alloy. A partially amorphous composition can refer to a composition of at least about 5 vol % of which is of an amorphous phase, such as at least about 10 vol %, such as at least about 20 vol %, such as at least about 40 vol %, such as at least about 60 vol %, such as at least about 80 vol %, such as at least about 90 vol %. The terms “substantially” and “about” have been defined elsewhere in this application. Accordingly, a composition that is at least substantially amorphous can refer to one of which at least about 90 vol % is amorphous, such as at least about 95 vol %, such as at least about 98 vol %, such as at least about 99 vol %, such as at least about 99.5 vol %, such as at least about 99.8 vol %, such as at least about 99.9 vol %. In one embodiment, a substantially amorphous composition can have some incidental, insignificant amount of crystalline phase present therein.

In one embodiment, an amorphous alloy composition can be homogeneous with respect to the amorphous phase. A substance that is uniform in composition is homogeneous. This is in contrast to a substance that is heterogeneous. The term “composition” refers to the chemical composition and/or microstructure in the substance. A substance is homogeneous when a volume of the substance is divided in half and both halves have substantially the same composition. For example, a particulate suspension is homogeneous when a volume of the particulate suspension is divided in half and both halves have substantially the same volume of particles. However, it might be possible to see the individual particles under a microscope. Another example of a homogeneous substance is air where different ingredients therein are equally suspended, though the particles, gases and liquids in air can be analyzed separately or separated from air.

A composition that is homogeneous with respect to an amorphous alloy can refer to one having an amorphous phase substantially uniformly distributed throughout its microstructure. In other words, the composition macroscopically comprises a substantially uniformly distributed amorphous alloy throughout the composition. In an alternative embodiment, the composition can be of a composite, having an amorphous phase having therein a non-amorphous phase. The non-amorphous phase can be a crystal or a plurality of crystals. The crystals can be in the form of particulates of any shape, such as spherical, ellipsoid, wire-like, rod-like, sheet-like, flake-like, or an irregular shape. In one embodiment, it can have a dendritic form. For example, an at least partially amorphous composite composition can have a crystalline phase in the shape of dendrites dispersed in an amorphous phase matrix; the dispersion can be uniform or non-uniform, and the amorphous phase and the crystalline phase can have the same or a different chemical composition. In one embodiment, they have substantially the same chemical composition. In another embodiment, the crystalline phase can be more ductile than the BMG phase.

The methods described herein can be applicable to any type of amorphous alloy. Similarly, the amorphous alloy described herein as a constituent of a composition or article can be of any type. The amorphous alloy can comprise the element Zr, Hf, Ti, Cu, Ni, Pt, Pd, Fe, Mg, Au, La, Ag, Al, Mo, Nb, Be, or combinations thereof. Namely, the alloy can include any combination of these elements in its chemical formula or chemical composition. The elements can be present at different weight or volume percentages. For example, an iron “based” alloy can refer to an alloy having a non-insignificant weight percentage of iron present therein, the weight percent can be, for example, at least about 20 wt %, such as at least about 40 wt %, such as at least about 50 wt %, such as at least about 60 wt %, such as at least about 80 wt %. Alternatively, in one embodiment, the above-described percentages can be volume percentages, instead of weight percentages. Accordingly, an amorphous alloy can be zirconium-based, titanium-based, platinum-based, palladium-based, gold-based, silver-based, copper-based, iron-based, nickel-based, aluminum-based, molybdenum-based, and the like. The alloy can also be free of any of the aforementioned elements to suit a particular purpose. For example, in some embodiments, the alloy, or the composition including the alloy, can be substantially free of nickel, aluminum, titanium, beryllium, or combinations thereof. In one embodiment, the alloy or the composite is completely free of nickel, aluminum, titanium, beryllium, or combinations thereof.

For example, the amorphous alloy can have the formula (Zr, Ti)a(Ni, Cu, Fe)b(Be, Al, Si, B)c, wherein a, b, and c each represents a weight or atomic percentage. In one embodiment, a is in the range of from 30 to 75, b is in the range of from 5 to 60, and c is in the range of from 0 to 50 in atomic percentages. Alternatively, the amorphous alloy can have the formula (Zr, Ti)a(Ni, Cu)b(Be)c, wherein a, b, and c each represents a weight or atomic percentage. In one embodiment, a is in the range of from 40 to 75, b is in the range of from 5 to 50, and c is in the range of from 5 to 50 in atomic percentages. The alloy can also have the formula (Zr, Ti)a(Ni, Cu)b(Be)c, wherein a, b, and c each represents a weight or atomic percentage. In one embodiment, a is in the range of from 45 to 65, b is in the range of from 7.5 to 35, and c is in the range of from 10 to 37.5 in atomic percentages. Alternatively, the alloy can have the formula (Zr)a(Nb, Ti)b(Ni, Cu)c(Al)d, wherein a, b, c, and d each represents a weight or atomic percentage. In one embodiment, a is in the range of from 45 to 65, b is in the range of from 0 to 10, c is in the range of from 20 to 40 and d is in the range of from 7.5 to 15 in atomic percentages. One exemplary embodiment of the aforedescribed alloy system is a Zr—Ti—Ni—Cu—Be based amorphous alloy under the trade name Vitreloy™, such as Vitreloy-1 and Vitreloy-101, as fabricated by Liquidmetal Technologies, CA, USA. Some examples of amorphous alloys of the different systems are provided in Table 1 and Table 2.

TABLE 1
Exemplary amorphous alloy compositions

| Alloy | Atm % | Atm % | Atm % | Atm % | Atm % | Atm % | Atm % | Atm % |
|---|---|---|---|---|---|---|---|---|
| 1 | Fe | Mo | Ni | Cr | P | C | B | |
| | 68.00% | 5.00% | 5.00% | 2.00% | 12.50% | 5.00% | 2.50% | |
| 2 | Fe | Mo | Ni | Cr | P | C | B | Si |
| | 68.00% | 5.00% | 5.00% | 2.00% | 11.00% | 5.00% | 2.50% | 1.50% |
| 3 | Pd | Cu | Co | P | | | | |
| | 44.48% | 32.35% | 4.05% | 19.11% | | | | |
| 4 | Pd | Ag | Si | P | | | | |
| | 77.50% | 6.00% | 9.00% | 7.50% | | | | |
| 5 | Pd | Ag | Si | P | Ge | | | |
| | 79.00% | 3.50% | 9.50% | 6.00% | 2.00% | | | |
| 6 | Pt | Cu | Ag | P | B | Si | | |
| | 74.70% | 1.50% | 0.30% | 18.0% | 4.00% | 1.50% | | |

TABLE 2
Additional Exemplary amorphous alloy compositions (atomic %)

| Alloy | Atm % | Atm % | Atm % | Atm % | Atm % | Atm % |
|---|---|---|---|---|---|---|
| 1 | Zr | Ti | Cu | Ni | Be | |
| | 41.20% | 13.80% | 12.50% | 10.00% | 22.50% | |
| 2 | Zr | Ti | Cu | Ni | Be | |
| | 44.00% | 11.00% | 10.00% | 10.00% | 25.00% | |
| 3 | Zr | Ti | Cu | Ni | Nb | Be |
| | 56.25% | 11.25% | 6.88% | 5.63% | 7.50% | 12.50% |
| 4 | Zr | Ti | Cu | Ni | Al | Be |
| | 64.75% | 5.60% | 14.90% | 11.15% | 2.60% | 1.00% |
| 5 | Zr | Ti | Cu | Ni | Al | |
| | 52.50% | 5.00% | 17.90% | 14.60% | 10.00% | |
| 6 | Zr | Nb | Cu | Ni | Al | |
| | 57.00% | 5.00% | 15.40% | 12.60% | 10.00% | |
| 7 | Zr | Cu | Ni | Al | | |
| | 50.75% | 36.23% | 4.03% | 9.00% | | |
| 8 | Zr | Ti | Cu | Ni | Be | |
| | 46.75% | 8.25% | 7.50% | 10.00% | 27.50% | |
| 9 | Zr | Ti | Ni | Be | | |
| | 21.67% | 43.33% | 7.50% | 27.50% | | |
| 10 | Zr | Ti | Cu | Be | | |
| | 35.00% | 30.00% | 7.50% | 27.50% | | |
| 11 | Zr | Ti | Co | Be | | |
| | 35.00% | 30.00% | 6.00% | 29.00% | | |
| 12 | Zr | Ti | Fe | Be | | |
| | 35.00% | 30.00% | 2.00% | 33.00% | | |
| 13 | Au | Ag | Pd | Cu | Si | |
| | 49.00% | 5.50% | 2.30% | 26.90% | 16.30% | |
| 14 | Au | Ag | Pd | Cu | Si | |
| | 50.90% | 3.00% | 2.30% | 27.80% | 16.00% | |
| 15 | Pt | Cu | Ni | P | | |
| | 57.50% | 14.70% | 5.30% | 22.50% | | |
| 16 | Zr | Ti | Nb | Cu | Be | |
| | 36.60% | 31.40% | 7.00% | 5.90% | 19.10% | |
| 17 | Zr | Ti | Nb | Cu | Be | |
| | 38.30% | 32.90% | 7.30% | 6.20% | 15.30% | |
| 18 | Zr | Ti | Nb | Cu | Be | |
| | 39.60% | 33.90% | 7.60% | 6.40% | 12.50% | |
| 19 | Cu | Ti | Zr | Ni | | |
| | 47.00% | 34.00% | 11.00% | 8.00% | | |
| 20 | Zr | Co | Al | | | |
| | 55.00% | 25.00% | 20.00% | | | |

Other exemplary ferrous metal-based alloys include compositions such as those disclosed in U.S. Patent Application Publication Nos. 2007/0079907 and 2008/0118387. These compositions include the Fe(Mn, Co, Ni, Cu) (C, Si, B, P, Al) system, wherein the Fe content is from 60 to 75 atomic percentage, the total of (Mn, Co, Ni, Cu) is in the range of from 5 to 25 atomic percentage, and the total of (C, Si, B, P, Al) is in the range of from 8 to 20 atomic percentage, as well as the exemplary composition Fe48Cr15Mo14Y2C15B6. They also include the alloy systems described by Fe—Cr—Mo—(Y,Ln)-C—B, Co—Cr—Mo-Ln-C—B, Fe—Mn—Cr—Mo—(Y,Ln)-C—B, (Fe, Cr, Co)—(Mo,Mn)—(C,B)—Y, Fe—(Co,Ni)—(Zr,Nb,Ta)—(Mo,W)—B, Fe—(Al,Ga)—(P,C,B,Si,Ge), Fe—(Co, Cr,Mo,Ga,Sb)—P—B—C, (Fe, Co)—B—Si—Nb alloys, and Fe—(Cr—Mo)—(C,B)—Tm, where Ln denotes a lanthanide element and Tm denotes a transition metal element. Furthermore, the amorphous alloy can also be one of the exemplary compositions Fe80P12.5C5B2.5, Fe80P11C5B2.5Si1.5, Fe74.5Mo5.5P12.5C5B2.5, Fe74.5Mo5.5P11C5B2.5Si1.5, Fe70Mo5Ni5P12.5C5B2.5, Fe70Mo5Ni5P11C5B2.5Si1.5, Fe68Mo5Ni5Cr2P12.5C5B2.5, and Fe68Mo5Ni5Cr2P11C5B2.5Si1.5, described in U.S. Patent Application Publication No. 2010/0300148.

The amorphous alloys can also be ferrous alloys, such as (Fe, Ni, Co) based alloys. Examples of such compositions are disclosed in U.S. Pat. Nos. 6,325,868; 5,288,344; 5,368,659; 5,618,359; and 5,735,975, Inoue et al., Appl. Phys. Lett., Volume 71, p 464 (1997), Shen et al., Mater. Trans., JIM, Volume 42, p 2136 (2001), and Japanese Patent Application No. 200126277 (Pub. No. 2001303218 A). One exemplary composition is Fe72A15Ga2P11C6B4. Another example is Fe72A17Zr1 0Mo5W2B15. Another iron-based alloy system that can be used in the coating herein is disclosed in U.S. Patent Application Publication No. 2010/0084052, wherein the amorphous metal contains, for example, manganese (1 to 3 atomic %), yttrium (0.1 to 10 atomic %), and silicon (0.3 to 3.1 atomic %) in the range of composition given in parentheses; and that contains the following elements in the specified range of composition given in parentheses: chromium (15 to 20 atomic %), molybdenum (2 to 15 atomic %), tungsten (1 to 3 atomic %), boron (5 to 16 atomic %), carbon (3 to 16 atomic %), and the balance iron.

The aforedescribed amorphous alloy systems can further include additional elements, such as additional transition metal elements, including Nb, Cr, V, and Co. The additional elements can be present at less than or equal to about 30 wt %, such as less than or equal to about 20 wt %, such as less than or equal to about 10 wt %, such as less than or equal to about 5 wt %. In one embodiment, the additional, optional element is at least one of cobalt, manganese, zirconium, tantalum, niobium, tungsten, yttrium, titanium, vanadium and hafnium to form carbides and further improve wear and corrosion resistance. Further optional elements may include phosphorous, germanium and arsenic, totaling up to about 2%, and preferably less than 1%, to reduce melting point. Otherwise incidental impurities should be less than about 2% and preferably 0.5%.

In some embodiments, a composition having an amorphous alloy can include a small amount of impurities. The impurity elements can be intentionally added to modify the properties of the composition, such as improving the mechanical properties (e.g., hardness, strength, fracture mechanism, etc.) and/or improving the corrosion resistance. Alternatively, the impurities can be present as inevitable, incidental impurities, such as those obtained as a byproduct of processing and manufacturing. The impurities can be less than or equal to about 10 wt %, such as about 5 wt %, such as about 2 wt %, such as about 1 wt %, such as about 0.5 wt %, such as about 0.1 wt %. In some embodiments, these percentages can be volume percentages instead of weight percentages. In one embodiment, the alloy sample/composition consists essentially of the amorphous alloy (with only a small incidental amount of impurities). In another embodiment, the composition includes the amorphous alloy (with no observable trace of impurities).

In one embodiment, the final parts exceeded the critical casting thickness of the bulk solidifying amorphous alloys.

In embodiments herein, the existence of a supercooled liquid region in which the bulk-solidifying amorphous alloy can exist as a high viscous liquid allows for superplastic forming. Large plastic deformations can be obtained. The ability to undergo large plastic deformation in the supercooled liquid region is used for the forming and/or cutting process. As oppose to solids, the liquid bulk solidifying alloy deforms locally which drastically lowers the required energy for cutting and forming. The ease of cutting and forming depends on the temperature of the alloy, the mold, and the cutting tool. As higher is the temperature, the lower is the viscosity, and consequently easier is the cutting and forming.

Embodiments herein can utilize a thermoplastic-forming process with amorphous alloys carried out between Tg and Tx, for example. Herein, Tx and Tg are determined from standard DSC measurements at typical heating rates (e.g. 20° C./min) as the onset of crystallization temperature and the onset of glass transition temperature.

The amorphous alloy components can have the critical casting thickness and the final part can have thickness that is thicker than the critical casting thickness. Moreover, the time and temperature of the heating and shaping operation is selected such that the elastic strain limit of the amorphous alloy could be substantially preserved to be not less than 1.0%, and preferably not being less than 1.5%. In the context of the embodiments herein, temperatures around glass transition means the forming temperatures can be below glass transition, at or around glass transition, and above glass transition temperature, but preferably at temperatures below the crystallization temperature Tx. The cooling step is carried out at rates similar to the heating rates at the heating step, and preferably at rates greater than the heating rates at the heating step. The cooling step is also achieved preferably while the forming and shaping loads are still maintained.

### Electronic Devices

The embodiments herein can be valuable in the fabrication of electronic devices using a BMG. An electronic device herein can refer to any electronic device known in the art. For example, it can be a telephone, such as a cell phone, and a land-line phone, or any communication device, such as a smart phone, including, for example an iPhone™, and an electronic email sending/receiving device. It can be a part of a display, such as a digital display, a TV monitor, an electronic-book reader, a portable web-browser (e.g., iPad™), and a computer monitor. It can also be an entertainment device, including a portable DVD player, conventional DVD player, Blue-Ray disk player, video game console, music player, such as a portable music player (e.g., iPod™), etc. It can also be a part of a device that provides control, such as controlling the streaming of images, videos, sounds (e.g., Apple TV™), or it can be a remote control for an electronic device. It can be a part of a computer or its accessories, such as the hard drive tower housing or casing, laptop housing, laptop keyboard, laptop track pad, desktop keyboard, mouse, and speaker. The article can also be applied to a device such as a watch or a clock.

### Embodiments

An embodiment provided herein includes a consumer electronics device having a housing including at least a bulk-solidifying amorphous alloy, at least one input/output port or jack, and a ductile coating at least over the bulk-solidifying amorphous alloy adjacent the at least one input/output port or jack.

Another embodiment provides a method of making a housing for a consumer electronics device that includes forming the housing from at least a bulk-solidifying amorphous alloy, the housing including at least one input/output port or jack. The method also includes positioning a ductile material adjacent the at least one input/output port or jack, and then joining the ductile material to the bulk-solidifying amorphous alloy.

Another embodiment provides a method of making a housing for a consumer electronics device that includes forming the housing from at least a bulk-solidifying amorphous alloy, the housing including at least one input/output port or jack. The method also includes coating a ductile material on the bulk-solidifying amorphous alloy in at least the area of the bulk-solidifying amorphous alloy that is adjacent to the at least one input/output port or jack.

The devices and methods described herein are useful in providing final articles having a variety of desired shapes and physical characteristics useful in forming a housing for a consumer electronics device. For example, a metal band surrounding a hand-held electronic device can be fabricated from a bulk-solidifying amorphous alloy material to provide a hard metal band, but various types of ductile materials, including metals, metal alloys, and plastics can be used in various portions of the band to provide desirable characteristics to the band. For example, in areas where a more ductile material is need, for example surrounding input/output ports, or metal pin ports, a more ductile material is desirable to avoid cracking and splitting of the more brittle bulk-solidifying amorphous material. These ductile materials may be placed in the appropriate positions in the mold, a bulk-solidifying amorphous alloy material then cast into the mold to produce the final desired shape of the band. Alternatively, the band could be formed from a bulk-solidifying amorphous material in which select areas, e.g., those adjacent to input/output ports, or metal pin ports having a recess formed therein in which a ductile material can be positioned or coated to form select areas having increased ductility. Another embodiment includes forming the entire input/output port, or metal pin port out of the ductile material by casting, joining, or coating the bulk-solidifying amorphous alloy housing in the appropriate portions of the housing. An additional embodiment includes forming a cladding or coating of ductile material over the entire bulk-solidifying amorphous alloy housing.

### An Exemplary Consumer Electronics Device

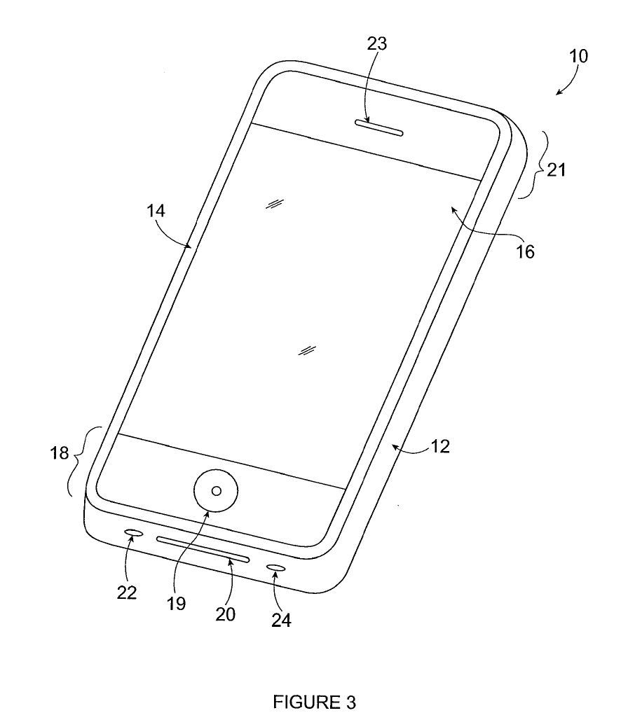

An illustrative portable electronic device in accordance with an embodiment is shown in FIG. 3. Device 10 of FIG. 3 may be, for example, a handheld electronic device that supports 2G, 3G, and/or 4G cellular telephone and data functions, global positioning system capabilities, and local wireless communications capabilities (e.g., IEEE 802.11 and Bluetooth®) and that supports handheld computing device functions such as internet browsing, email and calendar functions, games, music player functionality, etc. Device 10 may have a housing 12, or band. Antennas for handling wireless communications may be housed within housing 12 (as an example).

Housing 12, which is sometimes referred to as a case or band, can be fabricated from a bulk-solidifying amorphous alloy/foam material made in accordance with the embodiments described herein. In one embodiment, one or more portions of the housing may be processed to form a part of the antennas in device 10. For example, metal portions of housing 12 may be shorted to an internal ground plane in device 10 to create a larger ground plane element for that device 10.

Housing 12 may have a bezel 14. The bezel 14 may be formed from a conductive material or other suitable material. Bezel 14 may serve to hold a display or other device with a planar surface in place on device 10 and/or may serve to form an esthetically pleasing trim around the edge of device 10. As shown in FIG. 3, for example, bezel 14 may be used to surround the top of display 16. Bezel 14 and/or other metal elements associated with device 10 may be used as part of the antennas in device 10. For example, bezel 14 may be shorted to printed circuit board conductors or other internal ground plane structures in device 10 to create a larger ground plane element for device 10.

Display 16 may be a liquid crystal display (LCD), an organic light emitting diode (OLED) display, or any other suitable display. The outermost surface of display 16 may be formed from one or more plastic or glass layers. If desired, touch screen functionality may be integrated into display 16 or may be provided using a separate touch pad device. An advantage of integrating a touch screen into display 16 to make display 16 touch sensitive is that this type of arrangement can save space and reduce visual clutter.

Display screen 16 (e.g., a touch screen) is merely one example of an input-output device that may be used with electronic device 10. If desired, electronic device 10 may have other input-output devices. For example, electronic device 10 may have user input control devices such as button 19, and input-output components such as port 20 and one or more input-output jacks (e.g., for audio and/or video). Button 19 may be, for example, a menu button. Port 20 may contain a 30-pin data connector (as an example). Openings 22 and 24 may, if desired, form speaker and microphone ports. Speaker port 22 may be used when operating device 10 in speakerphone mode. Opening 23 may also form a speaker port. For example, speaker port 23 may serve as a telephone receiver that is placed adjacent to a user's ear during operation. In the example of FIG. 3, display screen 16 is shown as being mounted on the front face of handheld electronic device 10, but display screen 16 may, if desired, be mounted on the rear face of handheld electronic device 10, on a side of device 10, on a flip-up portion of device 10 that is attached to a main body portion of device 10 by a hinge (for example), or using any other suitable mounting arrangement.

A user of electronic device 10 may supply input commands using user input interface devices such as button 19 and touch screen 16. Suitable user input interface devices for electronic device 10 include buttons (e.g., alphanumeric keys, power on-off, power-on, power-off, and other specialized buttons, etc.), a touch pad, pointing stick, or other cursor control device, a microphone for supplying voice commands, or any other suitable interface for controlling device 10. Although shown schematically as being formed on the top face of electronic device 10 in the example of FIG. 3, buttons such as button 19 and other user input interface devices may generally be formed on any suitable portion of electronic device 10. For example, a button such as button 19 or other user interface control may be formed on the side of electronic device 10. Buttons and other user interface controls can also be located on the top face, rear face, or other portion of device 10. If desired, device 10 can be controlled remotely (e.g., using an infrared remote control, a radio-frequency remote control such as a Bluetooth® remote control, etc.).

Electronic device 10 may have ports such as port 20. Port 20, which may sometimes be referred to as a dock connector, 30-pin data port connector, input-output port, or bus connector, may be used as an input-output port (e.g., when connecting device 10 to a mating dock connected to a computer or other electronic device). Port 20 may contain pins for receiving data and power signals. Device 10 may also have audio and video jacks that allow device 10 to interface with external components. Typical ports include power jacks to recharge a battery within device 10 or to operate device 10 from a direct current (DC) power supply, data ports to exchange data with external components such as a personal computer or peripheral, audio-visual jacks to drive headphones, a monitor, or other external audio-video equipment, a subscriber identity module (SIM) card port to authorize cellular telephone service, a memory card slot, etc. The functions of some or all of these devices and the internal circuitry of electronic device 10 can be controlled using input interface devices such as touch screen display 16.

Components such as display 16 and other user input interface devices may cover most of the available surface area on the front face of device 10 (as shown in the example of FIG. 5) or may occupy only a small portion of the front face of device 10. Because electronic components such as display 16 often contain large amounts of metal (e.g., as radio-frequency shielding), the location of these components relative to the antenna elements in device 10 should generally be taken into consideration. Suitably chosen locations for the antenna elements and electronic components of the device will allow the antennas of electronic device 10 to function properly without being disrupted by the electronic components.

Examples of locations in which antenna structures may be located in device 10 include region 18 and region 21. These are merely illustrative examples. Any suitable portion of device 10 may be used to house antenna structures for device 10 if desired. In this embodiment, the bulk-solidifying amorphous alloy/foam composite material may be further processed in these areas by etching and then filling partially or wholly the voids (or hollow portions) remaining after etching with metals suitable for use in an antennae.

The area of housing or band 12 surrounding ports 20, 22, and 24, for example, may be designed to have a greater ductility or flexibility than other areas of housing 12. Use of a brittle bulk-solidifying amorphous alloy material in these areas may result in some of the material being broken, as connector pins, antenna jacks and other input devices are repeatedly inserted and withdrawn from the respective ports 20, 22, and 24. In these areas, a more ductile metal or metal alloy may be used to provide greater ductility in these select areas of housing or band 12.

### Forming the Ductile Areas

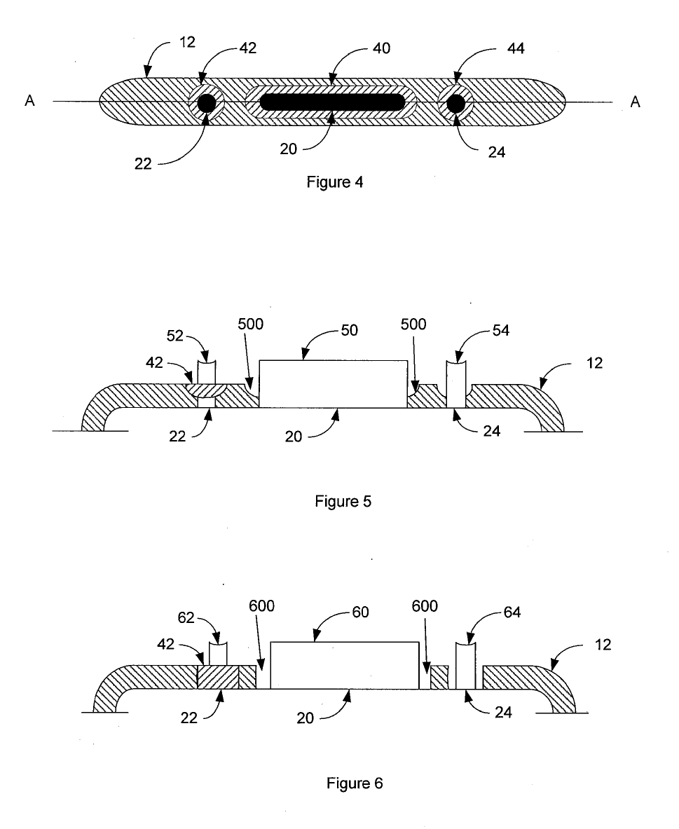

The formation of areas adjacent ports 20, 22, and 24 having greater ductility can be accomplished in a number of different embodiments. In one embodiment, these areas are coated with a ductile material to form a more ductile surface. In another embodiment, the entire area can be coated or filled to form a thicker ductile coating, or a ductile material can be positioned in these areas and then subsequently joined to the bulk-solidifying amorphous alloy. These embodiments, and other methods of forming a more ductile port in a consumer electronics device will be described in more detail below with reference to FIGS. 4, 5, and 6.

FIG. 4 is a view of the bottom of the portable electronic device of FIG. 3 in which the housing 12 is made from a bulk-solidifying amorphous alloy and the areas surrounding the ports 20, 22, and 24 are surrounded by ductile material 40, 42, and 44, respectively. While the areas surrounding the ports 20, 22, and 24 are shown in FIG. 4 as having roughly the same shape as the ports, it will be appreciated that the areas surrounding the ports may be rectangular, square, or any other suitable shape. Any suitable method can be used to provide ductile material 40, 42, and 44 in the respective areas on housing 12, including, for example, spray coating, (thermal, arc, or other forms of spray coating metals), insert casting, mold casting, diffusion bonding, and the like. If the melting point of the ductile material 40, 42, 44 is higher than the bulk-solidifying amorphous alloy material used to fabricate housing 12, in addition to the above-described methods, an alternative method includes forming ductile material 40, 42, 44 first, and then casting or spray coating the bulk-solidifying amorphous alloy onto the ductile material using a suitable mold apparatus.

One embodiment of forming areas containing a more ductile material 40, 42, 44 on housing 12 can be explained with reference to FIG. 5. FIG. 5 is a side view of the bottom portion of the portable electronic device of FIG. 3, shown along longitudinal axis A-A in FIG. 4. Only the bottom portion of housing 12 is shown in FIG. 5. As illustrated therein, housing 12, comprised of a bulk-solidifying amorphous alloy, can be formed to include through holes for ports 20, 22, and 24, and cut-outs 500 that can be filled, cast, or coated with a ductile material, shown as 42 in FIG. 5. A suitable mold material can be used to block through holes 20, 22, and 24, as shown by numerals 50, 52, and 54. The ductile material then can be coated, cast, or filled into the cut-outs 500, joined to bulk-solidifying amorphous alloy housing 12 in accordance with any of the joining techniques discussed below, and the mold materials 50, 52, and 54 removed to produce the bottom of the portable electronics device shown in FIG. 4.

While the cut-outs 500 shown in FIG. 5 have a rounded edge, much like a countersunk hole, the particular shape of the cut-outs 500 is not critical. The edges could be square or any other shape, so long as ductile material 40, 42, and 44 can be positioned therein or thereon and sufficiently joined to housing 12. The depth and overall size of cut-outs 500 also can be varied by those having ordinary skill in the art, depending, for example, on the size of the port 20, 22, 24, the composition of the bulk-solidifying amorphous alloy housing 12, the ductile material 40, 42, 44, and the intended use of the port. The particular ductile material used also may vary depending on the port such that the material used, for example, to form adjacent areas 42 and 44 may be more or less ductile than the ductile material used to form adjacent area 40.

Another embodiment of forming areas containing a more ductile material 40, 42, 44 on housing 12 can be explained with reference to FIG. 6. FIG. 6 is a side view of the bottom portion of the portable electronic device of FIG. 3, shown along longitudinal axis A-A in FIG. 4. Only the bottom portion of housing 12 is shown in FIG. 6. As illustrated therein, housing 12, comprised of a bulk-solidifying amorphous alloy, can be formed to include through holes for ports 20, 22, and 24, and cut-outs 600 that can be filled, cast, or coated with a ductile material, shown as 42 in FIG. 6. A suitable mold material can be used to block through holes 20, 22, and 24, as shown by numerals 60, 62, and 64. The ductile material then can be coated, cast, or filled into the cut-outs 600, joined to bulk-solidifying amorphous alloy housing 12 in accordance with any of the joining techniques discussed below, and the mold materials 60, 62, and 64 removed to produce the bottom of the portable electronics device shown in FIG. 4.

The cut-outs 600 illustrated in FIG. 6 completely surround ports 20, 22, and 24 and form a relatively straight-edged joint between the bulk-solidifying amorphous alloy housing 12, and the ductile material 42. The relatively straight-edged joint may provide a more secure joint between the respective materials, and need not be orthogonal to the bottom portion of housing 12, but rather could be wedge-shaped or conical shaped. In addition, while the cut-outs 600 are illustrated in FIG. 6 as traversing the entire cross-section of housing 12, they may only traverse a portion of the cross-section of housing 12. Ports 20, 22, and 24 also may only be partially recessed within the cross-section of housing 12, and the electrical connections placed therein, or ports 20, 22, and 24 may extend entirely through the cross-section of housing 12, thereby forming the electrical connection within the device. Those skilled in the art will appreciate other geometries and arrangements for ductile material 40, 42, and 44, as well as ports 20, 22, and 24, using the guidelines provided herein.

An additional embodiment not shown in the figures is forming a ductile coating or cladding layer over the entire surface of the bulk-solidifying amorphous housing 12. This can be accomplished by using a liquid phase coating technique (e.g., spraying, dip coating, etc.), by solid phase diffusion bonding (e.g., applying solid ductile layer and then heating to effect diffusion bonding), or adhering a film of ductile material on the bulk-solidifying amorphous alloy housing 12. Any of these techniques also could be used to form a ductile coating only in select areas of the housing 12.

### The Ductile Material

Any material having a ductility greater than the bulk-solidifying amorphous alloy used to form housing 12 can be used in the embodiments. Accordingly, the specific ductile material used will vary, depending in part on the composition of the bulk-solidifying amorphous alloy used to form housing 12. In one embodiment, the ductile material is a metal or alloy of the metal in which the specific metal used is also one of the metals used to form the bulk-solidifying amorphous alloy. In another embodiment, the ductile material is a metal or alloy of the metal in which the specific metal used is the most prominent metal used to form the bulk-solidifying amorphous alloy. In other embodiments, the ductile material is a metal or alloy of the metal in which the specific metal used is not one of the metals used to form the bulk-solidifying amorphous alloy. In other embodiments, the ductile material is a plastic material, or rubber material.

Examples of suitable ductile metals include, without limitation, one or more metals, or alloys of a metal selected from tantalum, niobium, molybdenum, iridium, rhodium, titanium, hafnium, zirconium, magnesium, rhenium, tungsten, gold, silver, platinum, iron, nickel, copper, aluminum, zinc, tin, lead, and alloys and mixtures thereof. The ductile metal or alloy of the metal may be comprised of a single metal, or may be an alloy of a number of metals. In addition to metals or alloys of metals, polymeric ductile materials also may be used in certain embodiments. Suitable ductile polymeric materials include, for example, polyolefins, rubbers, polymeric foams, polyacrylates, solidified gels, and mixtures thereof.

The particular ductile material used is not critical to the invention. In selecting the appropriate ductile material, the refractoriness, chemical inertness, ductility, and coefficient of expansion should be considered and compared with the respective properties of the bulk-solidifying amorphous alloy material. Decreasing ductility and increasing differences in expansion between the coating and the housing 12 may increase the likelihood of fracture within the layers or at the interface. Diffusion barrier materials may be used to ameliorate some of these concerns in which the diffusion barrier materials are comprised of the same or similar metals or alloys used in the ductile material and/or the bulk-solidifying amorphous alloy.

The ductile-brittle transition temperature (DBTT), or ductility temperature (NDT), or nil ductility transition temperature of a metal or metal alloy represents the point at which the fracture energy passes below a pre-determined point (for steels typically 40 J for a standard Charpy impact test). DBTT should be considered in selecting a suitable ductile material since, once a material is cooled below the DBTT, it has a much greater tendency to shatter on impact instead of bending or deforming. For example, Zamak® (a family of alloys with a base metal of zinc and alloying elements of aluminum, magnesium, and copper) exhibits good ductility at room temperature but shatters at sub-zero temperatures when impacted. DBTT should be considered in selection of the appropriate ductile material when the ductile material will be subjected to mechanical stresses. A similar phenomenon, the glass transition temperature, occurs with glasses and polymers, although the mechanism is different in these amorphous materials.

The most accurate method of measuring the BDT or DBT temperature of a material is by fracture testing. Typically, four point bend testing at a range of temperatures is performed on pre-cracked bars of polished material. For experiments conducted at higher temperatures, dislocation activity increases. At a certain temperature, dislocations shield the crack tip to such an extent the applied deformation rate is not sufficient for the stress intensity at the crack-tip to reach the critical value for fracture (K_{iC}). The temperature at which this occurs is the ductile-brittle transition temperature. If experiments are performed at a higher strain rate, more dislocation shielding is required to prevent brittle fracture and the transition temperature is raised. Another method of measuring the ductile-to-brittle transition temperature is using a miniaturized disc bending test technique as described in Eskner, et al., “Measurement of the ductile-to-brittle transition temperature in a nickel aluminide coating by a miniaturized disc bending technique,” Surface and Coatings Technology, 165, pp. 71-80 (2003).

### Forming the Coating or Layer

Any technique can be used to form the ductile material coating on the bulk-solidifying amorphous alloy material, and the specific technique employed will depend on the composition of the ductile material. When metals or alloys are used as the ductile material, casting, molding, spray coating, dip coating, chemical vapor deposition, plasma spraying, arc spraying, sputtering, electroplating, diffusion bonding, thermoforming and the like may be used. When polymeric ductile materials are used, they typically are applied to the bulk-solidifying amorphous materials using a conventional polymeric coating technique including, for example, spray coating, CVD, plasma coating, curtain coating, knife coating, dip coating, and the like.

One embodiment includes a chemical vapor deposition technique, such as that disclosed in, for example, EP 1501062 B1. The method includes chemical vapor deposition on a bulk-solidifying amorphous alloy in a chamber adapted for CVD involving at least the steps of: subjecting the bulk-solidifying amorphous alloy housing 12 to chemical vapor deposition with a flow of reactant gas comprising a ductile metal compound or alloy to be incorporated in the metal surface; and interrupting the chemical vapor deposition by cutting off the flow of reactant.

Another embodiment includes electroplating a ductile metal or alloy on at least one surface of a bulk-solidifying amorphous alloy. Electroplating can result in uniform coatings having substantially no porosity. For example, electroplating with refractory metals, e.g., tantalum and niobium, from molten salts and can be applied in chemical, metallurgical, pharmaceutical, medical industries, turbine manufacture, air- and spacecraft, and other areas of engineering, in creation of corrosion-resistant and barrier coatings. The bulk-solidifying amorphous alloy housing 12 can be immersed into a molten electrolyte containing fluorides of both refractory and alkali metal and a eutectic melt of sodium, potassium and caesium chlorides, the housing is heated to the working temperature of the electrolyte of 700-770° C. whereupon direct or reverse electric current is passed through the electrolyte, the current parameters being adjusted so that the quantity of electricity in the anodic Qa, and cathodic Qc, parts of the electroplating cycle corresponds to the ratio O≦Qa/Qc<0.9. To improve the quality it is desirable that the weight of the electrolyte exceeds that of the housing by 5 times or more. The technical result attained is the production of uniform-thickness, high quality tantalum or niobium coatings on a bulk-solidifying amorphous alloy that can be used as a housing for consumer electronics devices. Open porosity of the resulting coatings is not higher than 0.001%, adhesion to the substrate is as high as 8 kg/mm.

Another embodiment involves a CVD process in which an alloying zone is created between the bulk-solidifying amorphous alloy housing 12, and the ductile material 40, 42, 44. This process may involve applying a coating layer of the ductile material on all or a portion of the bulk-solidifying amorphous alloy housing 12 at a temperature within the range of from about 550 to about 1100° C., at a rate that ensures the formation of an alloying zone between the bulk-solidifying amorphous alloy housing 12 and the ductile material. The final article then is cooled and optionally subjected to mechanical modification such as, for example, rolling, imprinting by stroke or impact, and the like.

Other coating techniques involve liquid phase coatings that can be applied by atomizing a powder of the ductile material, and depositing the atomized powder on at least one surface of the bulk-solidifying amorphous alloy material. For example, thermal spraying can be used. A thermal spraying technique can include cold spraying, detonation spraying, flame spraying, high-velocity oxy-fuel coating spraying (HVOF), plasma spraying, warm spraying, wire arc spraying, or combinations thereof. The wire arc spraying can be carried out by twin-wire arc spraying (TWAS). The thermal spray can be carried out in one or more steps of operation.

The HVOF coatings can be dense with very low porosity (as aforedescribed) and/or little oxide inclusions and could be finished to low single digit room mean square (“Ra”) values, which is an indicator of the smoothness of the layer. The TWAS coatings in accordance with certain embodiments also may be dense, low in oxide stringers, and show good alloying of the cored wire. TWAS coating also can be finished to low Ra values.

When used for thermal spraying, such as HVOF, the ductile material thermal spray material preferably is fully alloyed or mixed. However, it need not be in an amorphous form, and even may have the ordinary macro-crystalline structure resulting from the normal cooling rates in the usual production procedures. Thus, the thermal spray powder may be made by such a standard method as atomizing from the melt and cooling the droplets under ambient conditions. The thermal spraying then melts the particles that quench on a surface being coated, providing a coating that may be substantially or entirely amorphous, although the embodiments are not limited to use of amorphous ductile materials. By using the usual manufacturing procedures, the production of the thermal spray powder is kept relatively simple and costs are minimized.

Thermal spraying can refer to a coating process in which melted (or heated) materials are sprayed onto a surface. The “feedstock” (coating precursor) can be heated by, for example, electrical (plasma or arc) or chemical means (combustion flame). Thermal spraying can provide thick coatings (e.g., thickness range of about 20 micrometers or more, such as to the millimeter range) over a large area at a high deposition rate, as compared to other coating processes. The feedstock can be fed into the system in powder or wire form, heated to a molten or semi-molten state, and then accelerated towards substrates in the form of micrometer-size particles. Combustion or electrical arc discharge can be used as the source of energy for thermal spraying. Resulting coatings can be made by the accumulation of numerous sprayed particles. Because the surface may not heat up significantly, thermal spray coating can have an advantage of allowing the coating of flammable substances.

A thermal spraying process generally includes three distinctive steps: the first step is to melt the material, the second is to atomize the material, and the third is to deposit the material onto the substrate. For example, an arc spraying process uses an electrical arc to melt the material and a compressed gas to atomize and deposit the material onto a substrate.

An embodiment useful in forming the ductile material coatings described herein is use of an HVOF process. The HVOF thermal spray process is substantially the same as the combustion powder spray process (“LVOF”) except that this process has been developed to produce extremely high spray velocity. There are a number of HVOF guns that use different methods to achieve high velocity spraying. One method is basically a high pressure water cooled combustion chamber and a long nozzle. Fuel (kerosene, acetylene, propylene and hydrogen) and oxygen are fed into the chamber, combustion produces a hot high pressure flame which is forced down a nozzle increasing its velocity. Powder may be fed axially into the combustion chamber under high pressure or fed through the side of a laval type nozzle where the pressure is lower. Another method uses a simpler system of a high pressure combustion nozzle and air cap. Fuel gas (propane, propylene or hydrogen) and oxygen are supplied at high pressure, and combustion occurs outside the nozzle but within an air cap supplied with compressed air. The compressed air pinches and accelerates the flame and acts as a coolant for the gun. Powder is fed at high pressure axially from the center of the nozzle.

In HVOF, a mixture of gaseous or liquid fuel and oxygen is fed into a combustion chamber, where they are ignited and combusted continuously. The resultant hot gas at a pressure close to 1 MPa emanates through a converging—diverging nozzle and travels through a straight section. The fuels can be gases (hydrogen, methane, propane, propylene, acetylene, natural gas, etc.) or liquids (kerosene, etc.). The jet velocity at the exit of the barrel (>1000 m/s) exceeds the speed of sound. A powder feed stock is injected into the gas stream, which accelerates the powder up to 800 m/s. The stream of hot gas and powder is directed towards the surface to be coated. The powder partially melts in the stream, and deposits upon the substrate. The resulting coating has low porosity and high bond strength.

HVOF coatings may be as thick as 12 mm (½″). It is typically used to deposit wear and corrosion resistant coatings on materials, such as ceramic and metallic layers. Common powders include WC—Co, chromium carbide, MCrAlY, and alumina. The process has been most successful and can be used for depositing cermet materials (WC—Co, etc.) and other corrosion-resistant alloys (stainless steels, nickel-based alloys, aluminum, hydroxyapatite for medical implants, etc.).

Another method of making the coatings of the embodiments herein is by an arc wire thermal spray process. In the arc spray process, a pair of electrically conductive wires are melted by means of an electric arc. The molten material is atomized by compressed air and propelled towards the substrate surface. The impacting molten particles on the substrate rapidly solidify to form a coating. This process carried out correctly is called a “cold process” (relative to the substrate material being coated) as the substrate temperature can be kept low during processing to avoid damage, metallurgical changes and distortion to the substrate material.

Another method of making the coatings of the embodiments herein can be by a plasma thermal spray process. The plasma spray process substantially involves spraying molten or heat softened material onto a surface to provide a coating. Material in the form of powder is injected into a very high temperature plasma flame, where it is rapidly heated and accelerated to a high velocity. The hot material impacts on the substrate surface and rapidly cools forming a coating. This process carried out correctly is called a “cold process” (relative to the substrate material being coated) as the substrate temperature can be kept low during processing to avoid damage, metallurgical changes and distortion to the substrate material.

The plasma gun comprises a copper anode and tungsten cathode, both of which are water cooled. Plasma gas (argon, nitrogen, hydrogen, helium) flows around the cathode and through the anode which is shaped as a constricting nozzle. The plasma is initiated by a high voltage discharge which causes localized ionization and a conductive path for a DC arc to form between the cathode and anode. The resistance heating from the arc causes the gas to reach extreme temperatures, dissociate, and ionize to form a plasma. The plasma exits the anode nozzle as a free or neutral plasma flame (plasma which does not carry an electric current) which is quite different from the plasma transferred arc coating process where the arc extends to the surface to be coated. When the plasma is stabilized and ready for spraying the electric arc extends down the nozzle, instead of shorting out to the nearest edge of the anode nozzle. This stretching of the arc is due to a thermal pinch effect. Cold gas around the surface of the water cooled anode nozzle being electrically non-conductive constricts the plasma arc, raising its temperature and velocity. Powder is fed into the plasma flame most commonly via an external powder port mounted near the anode nozzle exit. The powder is so rapidly heated and accelerated that spray distances can be in the order of 25 to 150 mm.

In one embodiment wherein the composition is used as a thermal spray material, the composition is desirably in an alloy form (as opposed to a composite of the constituents). Not to be bound to any particular theory, but desirable effects can be obtained during thermal spraying when the homogeneity of the sprayed composition is maximized—i.e., as an alloy, as opposed to a composite. In fact, alloyed powder of size and flowability suitable for thermal spraying can provide such a venue of homogeneity maximization. The powder particle can take any shape, such as spherical particles, elliptical particles, irregular shaped particles, or flakes, such as flat flakes. In one embodiment, the alloyed powder can have a particle size that falls in a range between 100-mesh (U.S. standard screen size—i.e., 149 microns) and about 2 microns. Furthermore, the thermal spray material may be used as is or, for example, as a powder blended with at least one other thermal spray powder, such as tungsten carbide.

Another embodiment for forming the ductile material coating includes liquid phase diffusion bonding wherein the bulk-solidifying amorphous material is in the solid phase and the ductile material is in the solid phase, and the two are heated in the presence of an insert material that melts, to effect interdiffusion between the respective materials. For example, liquid phase diffusion bonding is a joining technique interposing an insert material having a melting point lower than the joined members, for example, an amorphous metal or amorphous alloy, at the joining surfaces, heating to a temperature higher than a liquidus temperature of the insert material and a temperature lower than the melting point of the joined members, causing the joined parts to melt together, and causing isothermal solidification. The amorphous metal, amorphous alloy, or other insert material may, for example, be used in a foil, powder, plating, or other form.

According to liquid phase diffusion bonding, it is possible to simultaneously join a large number of locations. Further, when joining members with large cross-sectional areas of the joined parts, the required time does not greatly increase. For this reason, for the purpose of reducing installation costs, liquid phase diffusion bonding is now also being applied even to steel materials able to be joined by welding.

Other joining techniques suitable for joining the bulk-solidifying amorphous alloy housing and the ductile material coating or layer include solid phase diffusion, and thermoplastic forming. These processes are more readily suitable for use with ductile materials that are comprised mainly of metals or metal alloys. Generally, the joining process in the embodiments requires an application of heat to allow the respective materials to reach a temperature profile suitable for interdiffusion of the metals, alloys, plastics, and optionally, at a suitable pressure to bring the interface surfaces together to form a suitable bond between the ductile material 40, 42, 44 and the bulk-solidifying amorphous alloy housing 12. However, there are many different ways of applying heat, and optionally pressure, that can be used in accordance with the embodiments. Exemplary methods can be understood with reference to the continuous cooling transformation (CCT) schematic provided in FIG. 2. For clarity, the region in the bottom of FIG. 2 represents the solid phase while both crystalline and supercooled liquid occupy the upper portion of the diagram.

Suitable heating temperatures can range from about 100° C. to about 1,600° C., or from about 150° C. to about 1,000° C., or from about 175° C. to about 800° C., or from about 100° C. to about 750° C. In an embodiment, the housing 12 and ductile materials 40, 42, and 44 also are subjected to pressure during the heating. In one embodiment, the joint between the respective materials is formed using a thermoplastic process. This thermoplastic process is based on the unique rheological behavior and pattern-replication ability of bulk-solidifying amorphous alloys. More specifically, the method relies on three unique properties of these materials: (i) that an amorphous solid bulk-solidifying amorphous alloy specimen may be processed as a thermoplastic when heated above its glass transition temperature (Tg); (ii) that the Tg of these bulk-solidifying amorphous alloy materials is typically substantially below the melting temperature (Tm) of the material; and that the viscosity of these bulk-solidifying amorphous alloy materials continues to decrease with increasing temperature.

As shown in FIG. 2, under this thermoplastic process the bulk-solidifying amorphous alloy is heated to a temperature between the bulk-solidifying amorphous alloy material's glass transition (Tg) and melting (Tm) temperatures, and optionally, below its crystallization (Tx) temperature. At this temperature the bulk-solidifying amorphous alloy becomes a supercooled liquid. Because of the unique rheological properties of these bulk-solidifying amorphous alloys, wetting may take place in this supercooled liquid state as opposed to a molten state (above Tm) as would be required with a conventional solder material. Supercooled liquids, depending on their fragility, can have enough fluidity to spread under minor pressure. The fluidity of supercooled liquids of bulk-solidifying amorphous alloys is on par with thermoplastics during plastic injection molding. As a result, bulk-solidifying amorphous alloys under these thermoplastic conditions can be used as a thermoplastic joining material.

During the operation of the thermoplastic process the bulk-solidifying amorphous alloy housing 12 and the ductile material 40, 42, 44 are heated to a temperature above their glass transition temperature, into the supercooled liquid region. The preferred processing temperature is usually lower than the alloy's melting temperature and the crystallization kinetics are slow. As a result, the part can be held in the amorphous, supercooled liquid for a few minutes up to hours depending upon the particular amorphous alloy being used. Optionally this heating may be followed by mechanically pressing to minimize shrinkage and movement of the respective materials. The final coated article then may be cooled to room temperature.

In a thermoplastic process, the temperature (about Tg) is “decoupled” from the melting temperature of the bulk-solidifying amorphous alloy material (Tm). As a consequence, low temperature thermoplastic alloy formation can be achieved without lowering the melting temperatures of the bulk-solidifying amorphous material, allowing for an improved joint between the alloy and the ductile material. Moreover, after forming the joint, a wide variety of nano/microstructures from fully amorphous, partially-crystallized to fully-crystallized structures can be obtained through controlled crystallization via post-bonding annealing for optimum electrical conductivity, creep and fatigue properties tailored to a given application. It has been surprisingly discovered that this technique posts significant advantage over conventional joining methods, such as soldering, because the glass transition temperatures of the bulk-solidifying amorphous alloys are much lower than their melting point. Indeed, the amorphous thermoplastic alloying technique described herein typically requires a processing temperature range at a few hundred degrees (Celsius) below those required by conventional joining methods such as soldering, welding or brazing. As a result the deleterious effects of heat-effected zones, brittle oxide layers and unstable intermetallics typically found in conventional joining techniques can be reduced or eliminated.

Judiciously selecting the amorphous alloy system permits the thermoplastic joining technique to be used for a wide variety of bulk-solidifying amorphous alloy-to-ductile material joints, and is not limited to the applications found in any specific industry. Suitable processing conditions will depend on the different alloy family and composition, and the ductile material family and composition, a fuller description of which is provided below. For an example, a processing temperature may be 30-60° C. above Tg for gold and platinum based metals or metal alloy-containing joints. The Tg for one particular gold-bulk-solidifying amorphous alloy joint can be about 130° C. (J. Schroers, B. Lohwongwatana, W. L. Johnson and A. Peker, Applied Physics Letters 87 061912 (2005)), which means the thermoplastic joining process could be conducted at 160-170° C., which is significantly below the 210-230° C. processing temperature window for a conventional Sn-based solder. The method of forming the joint therefore takes place at a temperature outside the crystallization window shown in FIG. 2, and alloys interdiffusion between the bulk-solidifying amorphous metal and the at least one other metal or alloy of that metal used as the ductile material.

In another embodiment, embodiment A, the joint between the bulk-solidifying amorphous alloy housing 12 and the ductile material 40, 42, 44 can be heated to a temperature above Tm (of the housing 12). A pressure of about 150 pounds per square inch (psi) may be applied at that temperature. Inasmuch as there is substantially no tendency to transform to the crystalline state at this temperature, the housing 12 may be held at that temperature for an indefinitely long period until full contact along the interfaces between the housing 12 and ductile material 40, 42, 44, is achieved. For the purposes of determining the required cooling rate, the cooling rate should be sufficiently high that the cooling portion does not enter the crystalline field, which means that the cooling process should miss the nose of the crystalline field (FIG. 2). The selected cooling rate will usually be chosen to be the slowest cooling rate so that the joint passes by the nose, within the minimum clearance permitted by experimental or commercial tolerances. In common with quenching and cooling practice generally, overly high cooling rates can lead to high internal stresses within the joints between the bulk-solidifying amorphous alloy housing 12 and ductile material 40, 42, 44. It therefore may be preferred in some cases to use the embodiment B described below.

Another embodiment (embodiment B) includes a joining process conducted entirely below Tx. The bulk-solidifying amorphous alloy and at least the ductile material adjacent, ports 20, 22, 24, can be heated to a temperature above Tg but below Tx, the region where the crystalline phase field is receding downwardly and to the right (FIG. 2). The joining pressure then can be applied at this temperature. The joining pressure typically is higher than the pressure described in embodiment A above, because the viscosity of the bulk-solidifying amorphous material is higher at reduced temperature. At such a temperature, the time to transform to the crystalline state does not necessarily have to be translated back to the origin at the commencement of cooling as was the case for the embodiment described immediately above. Heating to the processing temperature is therefore normally performed reasonably rapidly, to permit as much time as possible for alloying and cooling, and to allow sufficient interdiffusion to form the alloy. Cooling should be started and should be sufficiently rapid to miss the crystalline state field. Accordingly, the crystallization temperature Tx should exceed the glass transition temperature Tg by an amount sufficient to permit the processing to be conducted in the interval between the two temperatures. It has been determined that, for conventional commercial practice, (Tx−Tg) should be at least about 30° C.

The approach of embodiment A achieves the formation of a suitable joint in a short time and with a low joining pressure, but requires relatively rapid cooling and therefore leads to a greater susceptibility to internal stresses within the final structure. The approach of embodiment B requires a higher joining pressure but is less susceptible to a buildup of internal stresses. Since the approach of embodiment B uses a lower temperature, it would be more suitable where one or all of the pieces that form the bulk-solidifying amorphous alloy housing 12 and ductile material areas 40, 42, 44, are previously heat treated to a particularly desirable structure or are themselves susceptible to thermal degradation. The selected approach will depend upon the geometries, structural heat sensitivity, and susceptibility to internal stresses (which could lead to bending or possible cracking) of the respective materials of the housing 12 and the ductile material 40, 42, and 44.

The selected joining processing sequence also depends upon the position and shape of the crystalline state field. FIG. 2 shows the nose of the crystalline state field at a time in the range of 1-100 minutes, which is typical for the compositions of the alloying elements to be discussed subsequently. Further innovations may be successful in moving the nose to longer times, permitting more flexibility in selecting processing sequences. If the nose can be moved sufficiently far to the right, joining processing sequences with processing temperatures between Tx and Tm, combined with a processing time and cooling rate to miss the nose of the crystalline field, may be practical in many situations.

The joining processing can be determined in conjunction with the selection of the composition of the bulk-solidifying amorphous alloy. A candidate initial composition for the bulk-solidifying amorphous alloy material may be selected, based in part upon the specific metal or alloy of that metal that will be used to form the ductile material. The initial composition should be capable of retaining an amorphous structure after cooling at a sufficiently high rate that is suitable for the proposed processing. It is preferred that the initial composition comprise at least three intentionally provided elements, as such compositions are found to be the most suitable for partial modification to the associated composition without loss of the ability to reach the amorphous state. The candidate composition is one that is known to be chemically and physically compatible with at least one metal or alloy of that metal used to form the ductile material.

In some embodiments, the bulk-solidifying amorphous alloy also may include some of the principal element(s) found in the at least one metal or alloy of that metal in the ductile material. As an example, if one of the metals in the ductile material is a titanium-base alloy and another metal is a zirconium-base alloy, the preferred bulk-solidifying amorphous alloy composition may either contain both titanium and zirconium, or is known to be tolerant of the presence of titanium and zirconium while retaining the amorphous state after processing. By this selection approach, there is a degree of certainty that there will be tolerated at least some additional material diffused into the joining element.

A number of specimens of a suitable bulk-solidifying amorphous material may be prepared, and then placed into contact with the at least one metal or metal alloy forming the ductile material, thus forming a series of trials. The trials then can be processed according to select joining methods, and evaluated to determine whether the bulk-solidifying amorphous material remained entirely amorphous. Those specimens that are entirely amorphous are concluded to be within a suitable alloying composition range.

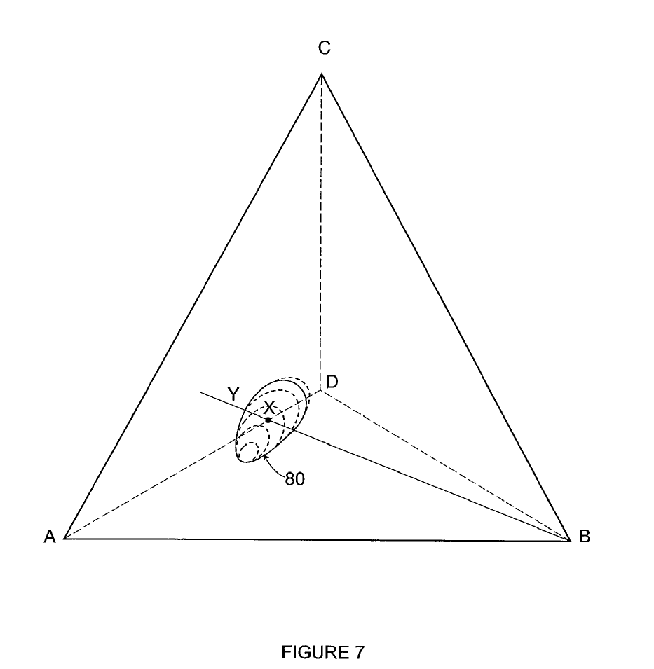

FIG. 7 illustrates a tetrahedral-plot approach for depicting the alloying composition range for a four component alloy system (A,B,C,D) wherein the alloy system includes, for example, an element B that is a principal component of the at least one metal or alloy of that metal that is used to form the ductile material. The alloy system (A,B,C,D) is known to be capable of achieving the amorphous state in at least some circumstances. A candidate initial composition for the bulk-solidifying amorphous alloy is selected and indicated on the plot of FIG. 7, for example, as point Y. Diffusion couples between alloys Y and B, prepared and analyzed according to the approach described above or by preparing and analyzing specimens of specific compositions, are plotted as to whether they are amorphous or crystalline. A surface drawn to divide the amorphous and crystalline regions then is the alloying composition range 80.

The composition Y should be suitable for forming an alloy when in contact with the at least other metal or alloy of metal, for example, element B, as just discussed, and also with any other metals or alloys of those metals used to form the ductile material. If additional metals or alloys of those metals are of the same composition as element B, no evaluation is required. If, on the other hand, the additional metals or alloys of those metals have a different principal constituent, e.g., element A, the stability of candidate composition Y as against A should also be determined. While seemingly complex, this evaluation process is straightforward in practice and well within the skill of those in the art, when using the guidelines provided herein.

Another suitable method for forming the joint between the bulk-solidifying amorphous alloy housing 12 and ductile material 40, 42, 44 described herein includes a deep undercoating process. This processing technique utilizes the deeply undercoating characteristic of bulk-solidifying amorphous alloys to form a liquid material that can be used to create alloys that can be amorphous, crystalline or partially crystalline.

In one process, a glassy alloy may be formed using a deeply undercooled glass forming liquid. In such a technique, the bulk-solidifying amorphous alloy and the ductile material are positioned adjacent one another in their respective positions, and then melted above Tm of the bulk-solidifying amorphous alloy, then quickly quenched to low temperature. The bulk-solidifying amorphous alloy portion of the joint has a stability against crystallization that allows the melted material to “vitrify” or freeze in the amorphous, state when the melt is deeply undercooled to below Tg. Once the temperature of the bulk-solidifying amorphous alloy material has been brought below Tg, it can then be further quenched to room temperature. The resulting joint may be fully amorphous if the cooling rate is sufficient to bypass crystallization as shown in the curve of FIG. 2.

It is not a coincidence that good glass forming liquids deeply undercoat before crystallization takes place. In other words, the liquid metal needs to undercoat deeply enough so that the temperature is low, the atomic mobility is restricted, and the atoms become “frozen” before they form crystals. Such a deep undercoating process also improves the chance that the joint between housing and ductile materials will solidify as an amorphous metal alloy.

Another joining method provides a joint that may have one or more crystalline or semi-crystalline phases. This method takes advantage of the deep undercoating properties of the bulk-solidifying amorphous alloy, but does not require the cooling rate to be fast enough to bypass the crystallization event. Crystallization still takes place, but the undercoating is large enough to minimize solidification shrinkage. There have been reports that crystalline-metallic glass composites have favorable mechanical properties, such as improved ductility, which would result in a more reliable joint. (See, C. C. Hays, C. P. Kim and W. L. Johnson, Physical Review Letters 84, 2901-2904 (2000))

In another embodiment, the bulk-solidifying amorphous housing 12 and ductile material 40, 42, 44 are subjected to plastic processing to form the joint. In this embodiment, plastic processing of the joint from the molten state is utilized. In this process the respective materials are heated above their melting temperatures, then each injected into a mold having the desired shape for the housing 12 and ductile material areas 40, 42, 44, whereby the mold is held at a predetermined lower temperature. The materials can be cooled to the deep supercooled liquid region quickly enough to avoid crystallization, at which point it can undergo thermoplastic processing. This process is similar to casting, but the respective materials are held below the crystallization “nose” (see FIG. 2) for a longer time, where it can be processed like a plastic. In such a method the temperature at which the thermoplastic processing takes place can be controlled by the mold's temperature.

The methods of the embodiments described herein are useful in providing bulk-solidifying amorphous alloy/ductile material joints having specifically tailored characteristics that render them particularly suitable for use in forming frames or housings of consumer electronics devices. Specifically, the bulk-solidifying amorphous materials can form the majority of the housing, and the ductile materials are positioned in areas on the housing surrounding input/output ports or jacks. The areas in which the ductile materials are to be positioned can be formed in-situ in a mold with the bulk-solidifying amorphous alloy housing 12, or may be formed after the housing is formed. The areas in which the ductile materials are to be positioned can be formed after housing 12 is formed by either forming housing 12 with recesses as shown, for example, in FIGS. 5 and 6, or the housing 12 can be formed first and then those recesses formed by milling or etching away the bulk-solidifying amorphous alloy. The ductile materials then can be positioned within the recesses or cavities, and then the article heated, and optionally pressed, to form a suitable joint between the bulk-solidifying amorphous alloy and the ductile material.

While the invention has been described in detail with reference to particularly preferred embodiments, those skilled in the art will appreciate that various modifications may be made thereto without significantly departing from the spirit and scope of the invention.

What is claimed:

1. A consumer electronics device comprising:
a housing including at least a bulk-solidifying amorphous alloy, the housing having at least one input/output port or jack; and
a ductile coating at least over the bulk-solidifying amorphous alloy adjacent the at least one input/output port or jack.

2. The consumer electronics device as claimed in claim 1, wherein the ductile coating at least partially surrounds the at least one input/output port or jack.

3. The consumer electronics device as claimed in claim 2, wherein the ductile coating completely surrounds the at least one input/output port or jack.

4. The consumer electronics device as claimed in claim 1, wherein the ductile coating is selected from a metal, a metal alloy, a plastic, a rubber, and mixtures thereof.

5. The consumer electronics device as claimed in claim 4, wherein the ductile coating is at least one material selected from the group consisting of tantalum, niobium, molybdenum, iridium, rhodium, titanium, hafnium, zirconium, magnesium, rhenium, tungsten, gold, silver, platinum, iron, nickel, copper, aluminum, zinc, tin, lead, and alloys and mixtures thereof.

6. The consumer electronics device as claimed in claim 4, wherein the ductile coating is at least one polymeric material selected from the group consisting of polyolefins, rubbers, polymeric foams, polyacrylates, solidified gels, and mixtures thereof.

7. The consumer electronics device as claimed in claim 1, wherein the bulk-solidifying amorphous alloy is described by the following molecular formula: (Zr, Ti)ₐ(Ni, Cu, Fe)_{b}(Be, Al, Si, B)_{c}, wherein “a” is in the range of from 30 to 75, “b” is in the range of from 5 to 60, and “c” is in the range of from 0 to 50 in atomic percentages.

8. The consumer electronics device as claimed in claim 1, wherein the bulk-solidifying amorphous alloy is described by the following molecular formula: (Zr, Ti)ₐ(Ni, Cu)_{b}(Be)_{c}, wherein “a” is in the range of from 40 to 75, “b” is in the range of from 5 to 50, and “c” is in the range of from 5 to 50 in atomic percentages.

9. The consumer electronics device as claimed in claim 1, wherein the bulk solidifying amorphous alloy can sustain strains up to 1.5% or more without any permanent deformation or breakage.

10. A method of making a housing for a consumer electronics device comprising:
forming at least a portion of the housing from at least one bulk-solidifying amorphous alloy such that the housing includes at least one input/output port or jack;
positioning a ductile material adjacent the at least one input/output port or jack; and
joining the ductile material to the bulk-solidifying amorphous alloy.

11. The method as claimed in claim 10, wherein joining the ductile material to the bulk-solidifying amorphous alloy comprises heating the materials to a temperature greater than the glass transition temperature and lower than the melting temperature of the bulk-solidifying amorphous alloy, optionally applying pressure, and cooling the materials to form the housing having a ductile material adjacent the at least one input/output port or jack.

12. The method as claimed in claim 10, wherein the ductile coating is selected from a metal, a metal alloy, a plastic, a rubber, and mixtures thereof.

13. The method as claimed in claim 12, wherein the ductile coating is at least one material selected from the group consisting of tantalum, niobium, molybdenum, iridium, rhodium, titanium, hafnium, zirconium, magnesium, rhenium, tungsten, gold, silver, platinum, iron, nickel, copper, aluminum, zinc, tin, lead, and alloys and mixtures thereof.

14. The method as claimed in claim 12, wherein the ductile coating is at least one polymeric material selected from the group consisting of polyolefins, rubbers, polymeric foams, polyacrylates, solidified gels, and mixtures thereof.

15. The method as claimed in claim 10, wherein the bulk-solidifying amorphous alloy is described by the following molecular formula: (Zr, Ti)ₐ(Ni, Cu, Fe)_{b}(Be, Al, Si, B)_{c}, wherein “a” is in the range of from 30 to 75, “b” is in the range of from 5 to 60, and “c” is in the range of from 0 to 50 in atomic percentages.

16. The method as claimed in claim 10, wherein the bulk-solidifying amorphous alloy is described by the following molecular formula: (Zr, Ti)ₐ(Ni, Cu)_{b}(Be)_{c}, wherein “a” is in the range of from 40 to 75, “b” is in the range of from 5 to 50, and “c” is in the range of from 5 to 50 in atomic percentages.

17. The method as claimed in claim 10, wherein the bulk solidifying amorphous alloy can sustain strains up to 1.5% or more without any permanent deformation or breakage.

18. A method of a housing for a consumer electronics device comprising:
forming at least a portion of the housing from at least a bulk-solidifying amorphous alloy such that the housing includes at least one input/output port or jack; and
coating a ductile material on the bulk-solidifying amorphous alloy in at least the area of the bulk-solidifying amorphous alloy that is adjacent to the at least one input/output port or jack.

19. The method as claimed in claim 18, wherein coating comprising using a high velocity thermal spraying process to form the coating.

20. The method of claim 19, wherein the high velocity thermal spraying process is selected from the group consisting of cold spraying, detonation spraying, flame spraying, high-velocity oxy-fuel coating spraying (HVOF), plasma spraying, warm spraying, wire arc spraying, twin-wire arc spraying (TWAS), or combinations thereof.
